(19) United States
(12) Patent Application Publication
(10) Pub. No.: US 2013/0284092 A1
(43) Pub. Date: Oct. 31, 2013

(54) FACEPLATE HAVING REGIONS OF DIFFERING EMISSIVITY

(71) Applicant: APPLIED MATERIALS, INC., Santa Clara, CA (US)

(72) Inventors: JAMES K. WILSON, New Fairfield, CT (US); WILLIAM A. HATHCOCK, Red Hook, NY (US); DAVID R. LEE, Danbury, CT (US)

(21) Appl. No.: 13/864,823

(22) Filed: Apr. 17, 2013

Related U.S. Application Data
(60) Provisional application No. 61/638,198, filed on Apr. 25, 2012.
(60) Provisional application No. 61/703,827, filed on Sep. 21, 2012.

(51) Int. Cl. C23C 16/455

(52) U.S. Cl. CPC C23C 16/455
USPC 118/715; 137/561 A

(57) ABSTRACT

Gas distribution apparatus for use in substrate processing chambers are disclosed. In some embodiments, gas distribution apparatus may include a faceplate to distribute a gas to a substrate. The faceplate includes a first side that faces the substrate. A central region of the first side has a first surface finish and a peripheral region of the first side has a second surface finish different than the first. A plurality of gas distribution holes are disposed through the faceplate to allow the gas to pass through the faceplate to a volume disposed on the first side of the faceplate. A rabbet may be disposed along an outer periphery of the faceplate on the first side with a ring disposed in the rabbet and removably coupled to the faceplate to form the peripheral region. The ring has a second side having the second surface finish that faces the substrate during use.

### CROSS-REFERENCE TO RELATED APPLICATIONS

This application claims benefit of U.S. provisional patent application Ser. No. 61/638,198, filed Apr. 25, 2012, and U.S. provisional patent application Ser. No. 61/703,827, filed Sep. 21, 2012, each of which are herein incorporated by reference in their entireties.

### FIELD

Embodiments of the present invention generally relate to semiconductor processing equipment.

### BACKGROUND

Integrated circuits comprise multiple layers of materials deposited by various techniques, including chemical vapor deposition (CVD). The deposition of materials on a semiconductor substrate via CVD is a critical step in the process of producing integrated circuits. The inventors have observed undesired non-uniformities in materials deposited on the substrate via CVD in certain applications. These non-uniformities lead to further costs incurred in planarizing or otherwise repairing the substrate prior to further processing or possible failure of the integrated circuit altogether.

The inventors believe that variance in the emissivity of the internal chamber components may lead to non-uniform heat distribution profiles within the chamber and, therefore, on the substrate. The inventors further believe that such non-uniformities in the heat distribution profile across the surface of the substrate further lead to the observed non-uniformities in the materials deposited on the substrate.

As such, the inventors have provided an improved apparatus for depositing materials on a substrate.

### SUMMARY

Embodiments of gas distribution apparatus for use in a substrate processing chamber having a substrate disposed within a processing volume of the substrate processing chamber are disclosed herein. In some embodiments, a gas distribution apparatus may include a faceplate to distribute a gas to a substrate, wherein the faceplate includes a first side that faces the substrate during use, and wherein a central region of the first side has a first surface finish and a peripheral region of the first side has a second surface finish that is different than the first surface finish; and a plurality of gas distribution holes disposed through the faceplate to allow the gas to pass through the faceplate to a volume disposed on the first side of the faceplate during use. In some embodiments, the apparatus may further include a rabbet disposed along an outer periphery of the faceplate on the first side; and a ring disposed in the rabbet and removably coupled to the faceplate to form the peripheral region of the faceplate, wherein the ring has a second side that faces the substrate during use, and wherein the second side has the second surface finish.

In some embodiments, a gas distribution apparatus for use in a substrate processing chamber having a substrate disposed within a processing volume of the substrate processing chamber may include a body having an inlet; a faceplate coupled to the body and defining, together with the body, a plenum positioned to receive a gas via the inlet, wherein the faceplate includes a first side that faces the substrate during use, and wherein the first side has a first surface finish; a plurality of gas distribution holes disposed through the faceplate and fluidly coupling the plenum to a volume disposed on the first side of the faceplate; a rabbet disposed along an outer periphery of the faceplate on the first side; and a ring disposed in the rabbet and removably coupled to the faceplate, wherein the ring has a second side that faces the substrate during use, and wherein the second side has a second surface finish that is different than the first surface finish.

In some embodiments, an apparatus for processing substrates having a gas distribution apparatus may include a chamber body having a substrate support disposed within a processing volume; a body having an inlet; a faceplate coupled to the body and opposing the substrate support, the faceplate and body at least partially defining a plenum to receive a gas via the inlet, wherein the faceplate includes a first side that faces the substrate support, and wherein a central region of the first side has a first surface finish and a peripheral region of the first side has a second surface finish that is different than the first surface finish; and a plurality of gas distribution holes disposed through the faceplate and fluidly coupling the plenum to the processing volume. In some embodiments, the apparatus may further include a rabbet disposed along an outer periphery of the faceplate on the first side; and a ring disposed in the rabbet and removably coupled to the faceplate to form the peripheral region of the faceplate, wherein the ring has a second side that faces the substrate support, and wherein the second side has the second surface finish.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a simplified cross-sectional view of an exemplary chemical vapor deposition chamber in accordance with some embodiments of the present invention.

FIG. 2 depicts a cross-sectional isometric view of a gas distribution apparatus in accordance with some embodiments of the present invention.

FIG. 3 depicts a bottom view of a faceplate in accordance with some embodiments of the present invention.

FIG. 4 depicts a cross-sectional side view of a faceplate in accordance with some embodiments of the present invention.

FIG. 5A depicts a cross-sectional isometric view of a gas distribution apparatus in accordance with some embodiments of the present invention.

FIG. 5B depicts a bottom view of a faceplate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the invention provide improved apparatus for depositing layers on substrates. Chemical vapor deposition (CVD), sub-atmospheric chemical vapor deposition (SACVD), rapid thermal chemical vapor deposition (RTCVD), and low pressure chemical vapor deposition (LPCVD) are all deposition methods that may be beneficially performed in the inventive apparatus. Examples of CVD processing chambers that may be modified in accordance with the teachings provided herein include the SiNgen®, SiNgen®-Plus, BTBAS, and POLYGEN™ chambers, all of which are commercially available from Applied Materials, Inc. of Santa Clara, Calif. Other process chambers that process substrates with thermally dependent processes (CVD or otherwise) may also benefit from modification according to the teachings provided herein, including process chambers available from other manufacturers.

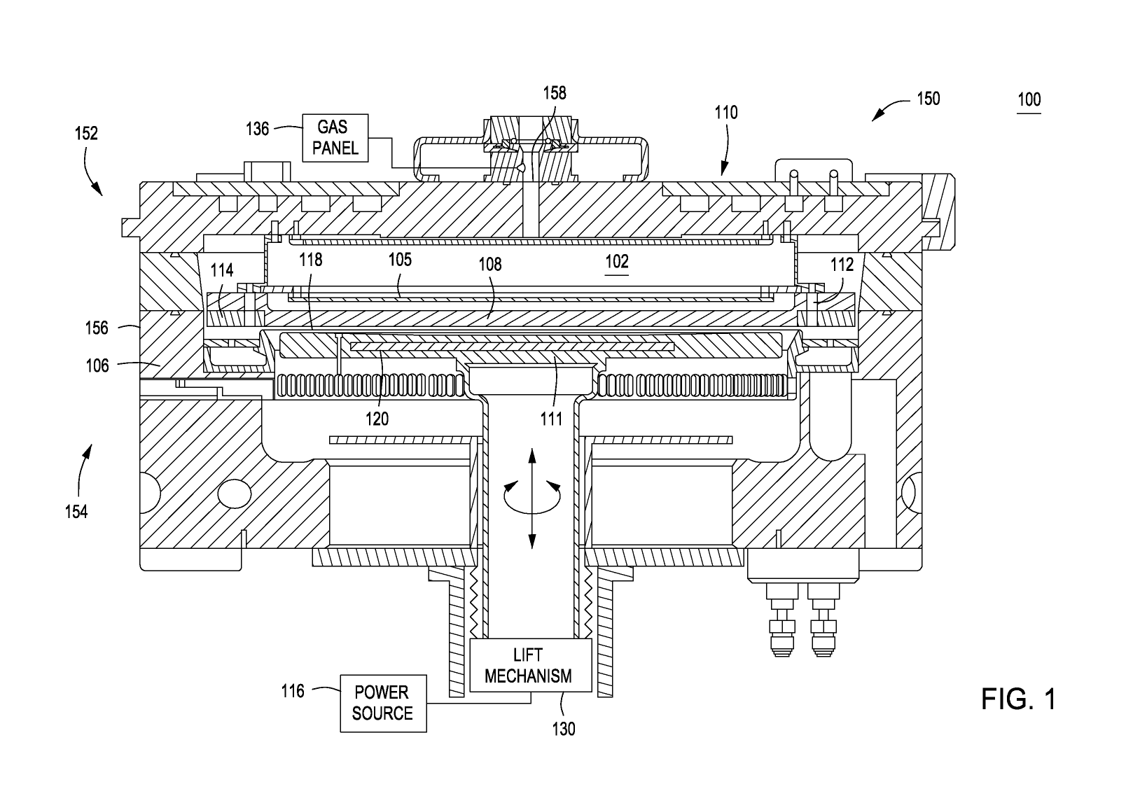

FIG. 1 is a cross sectional view of an illustrative single substrate CVD reactor 100. In some embodiments, and as depicted in FIG. 1, the reactor 100 may include a processing chamber 150. The processing chamber 150 generally includes a bottom assembly 154 and an upper assembly 152.

The bottom assembly 154 comprises a chamber body 156 having a wall 106 partially defining an interior of the processing chamber 150. A substrate support assembly 111 is disposed in the bottom assembly 154 for supporting a substrate (not shown) during processing. The substrate support assembly 111 may include a heater 120 configured to regulate the temperature of the substrate and/or temperature in the main processing volume 118 of the processing chamber 150. The heater 120 is coupled to the power source 116.

The upper assembly 152 comprises a body 110. In some embodiments, the body 110 may be a lid movably coupled, by a hinge or other suitable mechanism, to the lower assembly 154. In some embodiments, the body 110 has an inlet 158 through which process gas may enter the process chamber 150 from a gas panel 136, providing process chemicals, in liquid and/or gaseous form.

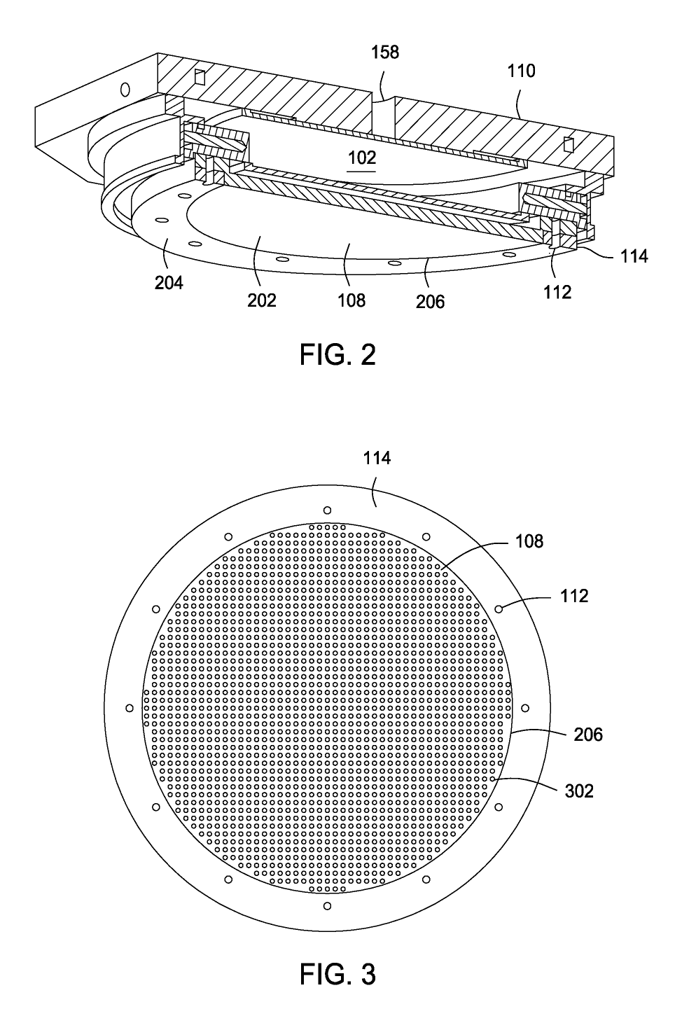

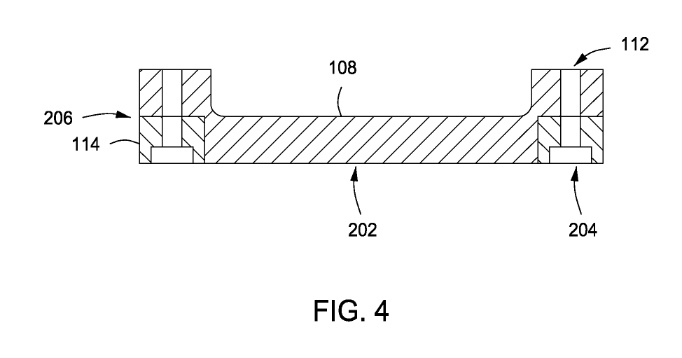

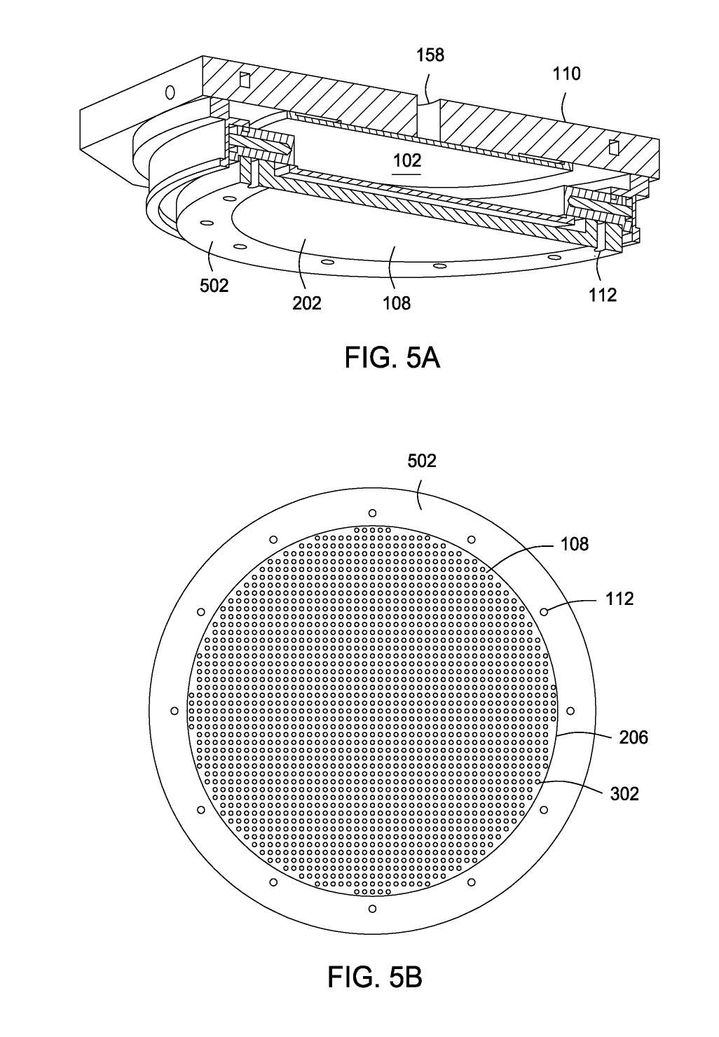

The body further comprises a plenum 102 and a faceplate 108. In some embodiments, the faceplate 108 is coupled to the body 110 and, together with the body 110, defines the plenum 102 for receiving a process gas via the inlet 158. As shown in FIG. 2, FIG. 4, and FIG. 5A, the faceplate 108 comprises a first side 202 facing the substrate during use. As shown in FIG. 3 and FIG. 5B, the faceplate 108 also comprises a plurality of gas distribution holes 302. The gas distribution holes 302 fluidly couple the plenum 102 to the main processing volume 118 disposed on the first side of the faceplate 108.

The faceplate 108 generally includes a central region having a first surface finish and a peripheral region surrounding the central region and having a second surface finish that is different than the first surface finish. The inventors have identified a correlation between the substrate temperature, which directly affects film uniformity on the surface of substrate, and the surface finish of the parts within the process chamber. The variation between the first surface finish and the second surface finish advantageously allows for the control of the substrate temperature, and in turn film uniformity, by controlling the amount of heat reflected toward the surface of the substrate from the central region of the faceplate 108 and the peripheral region of the faceplate 108.

For example, in some embodiments, as shown in FIGS. 1, 2, 3, and 4, a ring 114 is disposed within a rabbet 206 disposed along an outer periphery of the faceplate 108. The ring 114 corresponds to the peripheral region of the faceplate 108. The size of the ring 114, and corresponding rabbet 206, may vary depending upon the configuration of the processing equipment. In some embodiments, the ring 114 is sized such that the gas distribution holes are disposed solely through the faceplate 108, and no gas distribution holes are disposed through the ring 114. Such embodiments may advantageously prevent accumulation of deposited materials in the interface between the ring 114 and the faceplate 108 that could lead to particles undesirably being deposited on the substrate. Alternatively, in some embodiments, the ring 114 may be large enough such that some gas distribution holes pass through the ring 114.

As a non-limiting illustrative example, in equipment configured for processing a 300 mm semiconductor wafer, a faceplate may be about 13 inches in diameter and about 1 inch in overall thickness at least proximate the edge where the faceplate is mounted to the chamber lid (e.g., body 110). In such an exemplary embodiment, a rabbet may be provided about the outer diameter of the substrate-facing side of the faceplate. The rabbet may have a width of about 1.5 inches and a depth of about 0.5 inches. The ring 114 may have about the same dimensions as the rabbet—about 1.5 inches wide and about 0.5 inches thick so as to substantially fill the rabbet when installed.

The ring 114 is removably coupled to the faceplate 108, for example by screws or other suitable fasteners. In some embodiments, the ring 114 may be removably coupled to the faceplate 108 through mounting holes 112 disposed through the ring 114 to couple the faceplate 108 to the body 110, thereby facilitating ease of retro-fit of the faceplate to existing equipment.

The ring 114 and the faceplate 108 are both made of process-compatible materials that may vary depending upon the process to be performed in the processing chamber, such as aluminum, stainless steel, nickel-plated stainless steel, or the like. In some embodiments, the ring 114 and the faceplate 108 are both made of the same material. In some embodiments, the ring 114 and the faceplate 108 are made of different materials.

The ring 114 has a second side 204 that faces the substrate during operation of the reactor 100. In some embodiments, the second side 204 of the ring 114 and the first side 202 of the faceplate 108 are substantially co-planar. In some embodiments, the first side 202 of the faceplate 108 has a first surface finish and the second side 204 of the ring 114 has a second surface finish that is different from the first surface finish. Thus, the variation between the first surface finish and the second surface finish advantageously allows for the control of the substrate temperature, and in turn film uniformity, by controlling the amount of heat reflected toward the surface of the substrate from the first side 202 of the faceplate 108 and the second side 204 of the ring 114.

In some embodiments, for example during a nitride deposition process or an oxidation process, the amount of heat reflected to the center of the substrate may need to be suppressed while the amount of heat reflected to the peripheral edges of the substrate may need to be enhanced in order to create a uniformly deposited nitride film. In such embodiments, the first surface finish is configured to absorb radiation and the second surface finish is configured to reflect radiation. Alternatively, in some embodiments, the first surface finish is configured to reflect radiation and the second surface finish is configured to absorb radiation. More generally, the first surface finish and second surface finishes may be configured to absorb or reflect radiation in different relative amounts in order to impact the thermal profile of the substrate, and therefore, the desired characteristics (such as film thickness), for thermally driven or affected processes (such as the exemplary CVD deposition processes referred to above).

Alternatively or in combination, the second side 204 of the ring 114 may have a variety of different geometric configurations to further control the substrate temperature by controlling the direction of the radiation reflected off the second surface 204 of the ring 114 (e.g., a shaped surface). For example, in some embodiments, the second side 204 may be shaped to direct heat toward or away from a specific area on the surface of the substrate. For example, in some embodiments, the second side 204 may be angled toward or away from the center of the substrate. In some embodiments, a portion of the second side 204 may be angled toward or away from the center of the substrate. Such an angled configuration may be linear, curvilinear, or more complex geometries such as having one or more portions of the second side 204 having geometries to reflect or absorb radiation directed at various parts of the substrate.

In some embodiments, more than one ring may be disposed within the rabbet 206 along an outer periphery of the faceplate 108. In some embodiments, each ring is removably coupled to the faceplate 108 and each has a second side that faces the substrate during operation of the reactor 100. In some embodiments, the second side of each ring and the first side 202 of the faceplate 108 are substantially co-planar. In some embodiments, the second side of each ring has a surface finish that is different than each other. In some embodiments, the second side of at least one ring has a surface finish that is different than the first surface finish of the faceplate 108. In some embodiments, the second side of each ring has a different geometry as compared to each other.

Alternatively, and as depicted in FIGS. 5A and 5B, the faceplate 108 may be provided with a plurality of different surface finishes without the need for the ring 114. For example, the first side 202 of the faceplate 108 may have a first surface finish and a peripheral region 502 of the faceplate 108 may be provided with a second surface finish that is different from the first surface finish. The above discussion relating to the relative size of the ring and the number and type of surface finishes of the ring also apply to the relative size and surface finishes provided in the peripheral region 502.

Thus, improved apparatus for depositing films on a substrate have been disclosed herein. The inventive apparatus may advantageously facilitate one or more of depositing films having reduced film non-uniformity within a given process chamber. For example, embodiments of the improved apparatus provide faceplates having different surface conditions and finishes. In some embodiments, the surface conditions and finishes may be customizable by using interchangeable rings and faceplates. On-wafer process results, modeling, or other suitable techniques may be used to select and optimize the specific ring-faceplate combination.

While the foregoing is directed to embodiments of the present invention, other and further embodiments of the invention may be devised without departing from the basic scope thereof.

1. A gas distribution apparatus for use in a substrate processing chamber having a substrate disposed within a processing volume of the substrate processing chamber, comprising:
a faceplate to distribute a gas to a substrate, wherein the faceplate includes a first side that faces the substrate during use, and wherein a central region of the first side has a first surface finish and a peripheral region of the first side has a second surface finish that is different than the first surface finish; and
a plurality of gas distribution holes disposed through the faceplate to allow the gas to pass through the faceplate to a volume disposed on the first side of the faceplate during use.

2. The apparatus of claim 1, further comprising:
a rabbet disposed along an outer periphery of the faceplate on the first side; and
a ring disposed in the rabbet and removably coupled to the faceplate to form the peripheral region of the faceplate, wherein the ring has a second side that faces the substrate during use, and wherein the second side has the second surface finish.

3. The apparatus of claim 2, wherein the ring and the faceplate are fabricated from the same material.

4. The apparatus of claim 2, wherein the ring and the faceplate are fabricated from different materials.

5. The apparatus of claim 2, wherein the second side is not coplanar with the first side of the faceplate and is shaped to direct radiation in a desired direction.

6. The apparatus of claim 2, wherein the first side and the second side are substantially co-planar.

7. The apparatus of claim 2, wherein the first side and the second side are substantially co-planar, and wherein the first side and the second side have different surface finishes.

8. The apparatus of claim 7, wherein the first surface finish is configured to absorb radiation, and wherein the second surface finish is configured to reflect radiation.

9. The apparatus of claim 2, wherein the faceplate further comprises a plurality of mounting holes disposed through the faceplate to mount the faceplate to a lid of the substrate processing chamber, and wherein the ring is coupled to the faceplate through at least some of the plurality of mounting holes.

10. The apparatus of claim 2, further comprising a plurality of rings disposed in the rabbet.

11. The apparatus of claim 10, wherein the plurality of rings each comprise a second side having a different second surface finish as compared to each other.

12. The apparatus of claim 1, wherein the first surface finish is configured to absorb radiation, and wherein the second surface finish is configured to reflect radiation.

13. The apparatus of claim 1, wherein all of the gas distribution holes are disposed through the faceplate in the central region.

14. A gas distribution apparatus for use in a substrate processing chamber having a substrate disposed within a processing volume of the substrate processing chamber, comprising:
a body having an inlet;
a faceplate coupled to the body and defining, together with the body, a plenum positioned to receive a gas via the inlet, wherein the faceplate includes a first side that faces the substrate during use, and wherein the first side has a first surface finish;
a plurality of gas distribution holes disposed through the faceplate and fluidly coupling the plenum to a volume disposed on the first side of the faceplate;
a rabbet disposed along an outer periphery of the faceplate on the first side; and
a ring disposed in the rabbet and removably coupled to the faceplate, wherein the ring has a second side that faces the substrate during use, and wherein the second side has a second surface finish that is different than the first surface finish.

15. An apparatus for processing substrates having a gas distribution apparatus, comprising:
a chamber body having a substrate support disposed within a processing volume;
a body having an inlet;
a faceplate coupled to the body and opposing the substrate support, the faceplate and body at least partially defining a plenum to receive a gas via the inlet, wherein the faceplate includes a first side that faces the substrate support, and wherein a central region of the first side has a first surface finish and a peripheral region of the first side has a second surface finish that is different than the first surface finish; and
a plurality of gas distribution holes disposed through the faceplate and fluidly coupling the plenum to the processing volume.

16. The apparatus of claim 15, further comprising:
a rabbet disposed along an outer periphery of the faceplate on the first side; and
a ring disposed in the rabbet and removably coupled to the faceplate to form the peripheral region of the faceplate, wherein the ring has a second side that faces the substrate support, and wherein the second side has the second surface finish.

17. The apparatus of claim 16, wherein the ring and the faceplate are fabricated from the same material.

18. The apparatus of claim 16, wherein the second side is not coplanar with the first side of the faceplate and is shaped to direct radiation in a desired direction.

19. The apparatus of claim 16, wherein the first side and the second side are substantially co-planar, and wherein the first side and the second side have different surface finishes.

20. The apparatus of claim 15, wherein the first surface finish is configured to absorb radiation, and wherein the second surface finish is configured to reflect radiation.
